(19) United States
(12) Patent Application Publication
(10) Pub. No.: US 2003/0080334 A1
(43) Pub. Date: May 1, 2003

(54) Semiconductor device having test element and method of testing using same

(75) Inventor: Eiji Yoshida, Tokyo (JP)

Correspondence Address: OBLON, SPIVAK, MCCLELLAND, MAIER & NEUSTADT, P.C., 1940 DUKE STREET, ALEXANDRIA, VA, 22314, US

(73) Assignee: MITSUBISHI DENKI KABUSHIKI KAISHA, Tokyo (JP)

(21) Appl. No.: 10/133,483

(22) Filed: Apr. 29, 2002

(30) Foreign Application Priority Data
Oct. 30, 2001 (JP) 2001-332146

(51) Int. Cl. H01L 23/58; H01L 27/15; H01L 31/12; H01L 31/153; H01L 33/00

(52) U.S. Cl. 257/48; 257/84; 257/292

(57) ABSTRACT

A CMOS transmission gate (9) serving as a test element is connected to an input of a semiconductor element to be tested through an interconnect line (13), and an input signal is applied to the semiconductor element through the CMOS transmission gate (9). The application of the input signal causes a potential change to occur at PN junction surfaces between source/drain regions (7a, 7b, 8a, 8b) of N-channel and P-channel MOS transistors (NT1, PT1) constituting the CMOS transmission gate (9) and wells (1, 2). An LVP (Laser Voltage Probe) technique is used to direct a near infrared laser beam (10) onto the PN junction surfaces through the backside of a semiconductor substrate (15), and to measure the intensity of a reflected beam from the PN junction surfaces, thereby detecting the potential change at the PN junction surfaces.

### BACKGROUND OF THE INVENTION

1. Field of the Invention

The present invention relates to a semiconductor device having a test element for locating an internal failure of a semiconductor element to be tested and for analyzing signal transmission timing and a signal function level in the semiconductor element, and to a method of testing using the same.

2. Description of the Background Art

In the field of semiconductor device failure analysis techniques, there is a demand for locating failures more rapidly. To locate failures in a larger-scale higher-functionality semiconductor device, it is not sufficient to only examine defect information outputted to the outside but it is necessary to also examine transmission paths of information in internal circuits of the semiconductor device.

At the present time, semiconductor devices have a tendency toward an increasing level of multi-layer interconnection and an increasing level of diversity of device configurations such as LOC (Lead On Chip), CSP (Chip Size/Scale Package) and flip chips. Semiconductor devices have accordingly complicated interconnect lines in the circuits thereof. It is, hence, becoming difficult to locate failures only by accessing a semiconductor element to be tested for failures from the front side thereof.

To overcome the difficulties, an LVP (Laser Voltage Probe) technique has been developed which uses a near infrared laser beam as a probe to test a semiconductor element to be tested from the backside thereof in a non-contacting manner. The LVP technique comprises measuring the intensity of the reflected near infrared laser beam to measure a potential change in an impurity diffused region, an channel region under a gate electrode and the like in the semiconductor element.

With reference to FIG. 11, the LVP technique will be described in detail, taking a CMOS (Complementary Metal Oxide Semiconductor) inverter as an example of the semiconductor element under test. As illustrated in FIG. 11, the semiconductor element (or the CMOS inverter) 5 comprises an N-channel MOS transistor NT2 and a P-channel MOS transistor PT2 both formed on a semiconductor substrate 15 such as a silicon substrate. The N-channel MOS transistor NT2 has source/drain regions 107a, 107b formed in a P-type well 101, and a gate electrode 106a overlying a channel region 103. The P-channel MOS transistor PT2 has source/drain regions 108a, 108b formed in an N-type well 102, and a gate electrode 106b overlying a channel region 104.

A near infrared laser beam 10 is directed onto the semiconductor element 5 through the backside of the semiconductor substrate 15. The direction of the near infrared laser beam 10 is controlled so that the near infrared laser beam 10 passes through the semiconductor substrate 15 to reach PN junction surfaces and the channel regions in impurity diffused regions (the source/drain regions and wells). Part of the near infrared laser beam 10 is reflected from the PN junction surfaces to create a reflected beam. The semiconductor element 5 is brought into a transistor operation, and a photodetector (not shown) measures the intensity of the reflected beam during the transistor operation.

The near infrared laser beam 10 reflected from the PN junction surfaces has different intensities due to a potential difference between P-type and N-type regions. Thus, measuring the intensity of the near infrared laser beam 10 reflected from the PN junction surfaces allows the detection of a potential change at PN junction surfaces between the source/drain regions 107a, 107b and the well 101, a potential change at PN junction surfaces between the source/drain regions 108a, 108b and the well 102 and a potential change between inversion layers in the respective channel regions 103, 104 and the wells 101, 102, all of which occur in the switching operation of the semiconductor element 5.

The detection of these potential changes allows, for example, the detection of a line-break, and the analysis of functions and timing of signal changes.

Unfortunately, a region measurable by the LVP technique is limited to PN junction surfaces (including not only the junction surfaces between the source/drain regions and the well but also a PN junction surface between the inversion layer and the well). Therefore, the measurable region in the semiconductor element 5, or the CMOS inverter, is limited to the PN junction surfaces and channel regions in the impurity diffused regions.

Thus, the LVP technique is capable of detecting a signal change at an output (on an interconnect line 14 side) of the CMOS inverter, but not at an input (on an interconnect line 13 side) thereof.

To locate internal failures of the semiconductor element under test and analyze signal transmission timing in the semiconductor element under test rapidly and precisely, it is not sufficient to be capable of detecting the signal change only at the output of the semiconductor element under test but it is necessary to detect the signal change also at the input thereof. Without comparison between the signal change at the input and the signal change at the output, it is impossible to determine whether an interconnect line extending to the input of the semiconductor element under test or the semiconductor element under test itself has a problem and to determine the time required for signal transmission between the input and the output.

### SUMMARY OF THE INVENTION

It is an object of the present invention to provide a semiconductor device having a test element capable of detecting a signal change also at an input of a semiconductor element to be tested by the use of an LVP technique, and a method of testing using the same.

An aspect of the present invention is intended for a semiconductor device having a test element. According to the present invention, the semiconductor device includes a semiconductor element to be tested, and a MIS (metal insulator semiconductor) transistor. The semiconductor element is formed on a semiconductor substrate and has an input and an output. The MIS transistor is formed on the semiconductor substrate and serves as the test element. The MIS transistor has a source region defined by a first PN junction surface, a drain region defined by a second PN junction surface, and a gate electrode. One of the source region and the drain region is connected to the input of the semiconductor element.

In the semiconductor device according to the present invention, one of the source region and the drain region of the MIS transistor serving as the test element is connected to the input of the semiconductor element. Application of an input signal to the input of the semiconductor element causes a potential change to occur at the PN junction surface of the one of the source and drain regions of the MIS transistor which is connected to the input of the semiconductor element. The use of an LVP technique to detect the potential change at the PN junction surface allows the inspection of the semiconductor element also for a signal change at the input thereof.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a circuit diagram of a semiconductor device having a test element according to a first preferred embodiment of the present invention;

FIG. 2 is a sectional view showing a structure of the semiconductor device having the test element according to the first preferred embodiment;

FIG. 3 is a circuit diagram of the semiconductor device having the test element according to a second preferred embodiment of the present invention;

FIG. 4 is a sectional view showing a structure of the semiconductor device having the test element according to the second preferred embodiment;

FIG. 5 is a circuit diagram of the semiconductor device having the test element according to a third preferred embodiment of the present invention;

FIG. 6 is a sectional view showing a structure of the semiconductor device having the test element according to the third preferred embodiment;

FIG. 7 is a circuit diagram of the semiconductor device having the test element according to a fourth preferred embodiment of the present invention;

FIG. 8 is a sectional view showing a structure of the semiconductor device having the test element according to the fourth preferred embodiment;

FIG. 9 is a circuit diagram of the semiconductor device having the test element according to a fifth preferred embodiment of the present invention;

FIG. 10 is a sectional view showing a structure of the semiconductor device having the test element according to the fifth preferred embodiment; and

FIG. 11 is a sectional view showing a semiconductor element under test to which an LVP technique is applied.

### DESCRIPTION OF THE PREFERRED EMBODIMENTS

<First Preferred Embodiment>

A first preferred embodiment of the present invention discloses a semiconductor device having a test element in which a CMOS transmission gate serving as the test element is connected to an input of a semiconductor element to be tested. Additionally disclosed is a testing method capable of inspecting the semiconductor element for a signal change at the input thereof by applying an LVP technique to the semiconductor device.

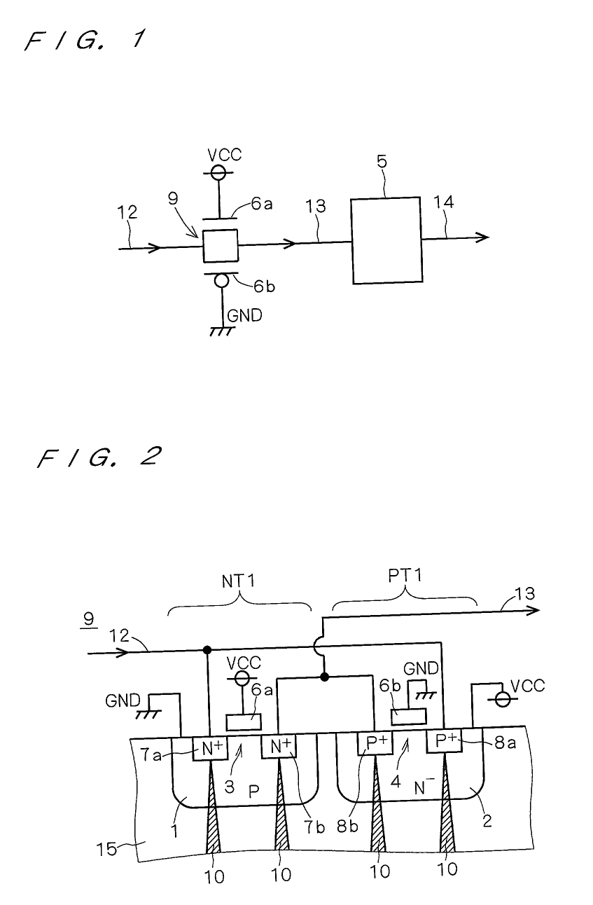

FIGS. 1 and 2 are a circuit diagram and a sectional view, respectively, of the semiconductor device according to the first preferred embodiment. In the semiconductor device, as illustrated in FIG. 1, an output of a CMOS transmission gate 9 serving as a test element is connected through an interconnect line 13 to an input of a semiconductor element 5 to be tested, and an input signal to the semiconductor element 5 is applied through an interconnect line 12 to an input of the CMOS transmission gate 9.

The semiconductor element 5 is, for example, a CMOS inverter as shown in FIG. 11. Other examples of the semiconductor element 5 used herein may include a one-transistor, one-capacitor (“1T-1C”) memory cell for use in a memory circuit, and an NAND circuit and a flip-flop circuit for use in a logic circuit.

With reference to FIG. 2, the CMOS transmission gate 9 comprises an N-channel MOS transistor NT1 and a P-channel MOS transistor PT1 both formed on a semiconductor substrate 15. Although not shown in FIG. 2, the semiconductor element 5 is also formed adjacent to the CMOS transmission gate 9 on the semiconductor substrate 15.

The N-channel MOS transistor NT1 has source/drain regions 7a, 7b formed in a P-type well 1, and a gate electrode 6a overlying a channel region 3. The P-channel MOS transistor PT1 has source/drain regions 8a, 8b formed in an N-type well 2, and a gate electrode 6b overlying a channel region 4.

A power supply potential VCC is applied to the gate electrode 6a, and a ground potential GND is applied to the gate electrode 6b. Thus, both of the N-channel MOS transistor NT1 and the P-channel MOS transistor PT1 are normally maintained in the on state. The ground potential GND is applied to the well 1 and the power supply potential VCC is applied to the well 2. The wells 1 and 2 are fixed at those potentials, respectively.

The source/drain regions 7a and 8a serve as the input of the CMOS transmission gate 9. The source/drain regions 7b and 8b serve as the output of the CMOS transmission gate 9 (i.e., are connected to the input of the semiconductor element 5).

With the CMOS transmission gate 9 thus connected to the input of the semiconductor element 5, application of an input signal to the input of the semiconductor element 5 causes a potential change at PN junction surfaces between the source/drain regions 7b, 8b of the N-channel and P-channel MOS transistors NT1, PT1 constituting the CMOS transmission gate 9 and the wells 1, 2, respectively.

The semiconductor device having the test element according to the first preferred embodiment can use the LVP technique to direct a near infrared laser beam 10 onto the PN junction surfaces through the backside of the semiconductor substrate 15 and to measure the intensity of the near infrared laser beam 10 reflected from the PN junction surfaces, thereby detecting the potential change at the PN junction surfaces.

The detection of the potential change at the above-mentioned PN junction surfaces by the LVP technique using the semiconductor device according to the first preferred embodiment achieves a testing method capable of inspecting the semiconductor element 5 for the signal change also at the input thereof.

In the first preferred embodiment, the input signal to the semiconductor element 5 under test is applied to the source/drain regions 7a, 8a of the N-channel and P-channel MOS transistors NT1, PT1. The transistors NT1 and PT1 are normally maintained in the on state, and the remaining source/drain regions 7b, 8b thereof are connected to the input of the semiconductor element 5.

Thus, the input signal is transmitted through the source/drain regions 7a, 7b, 8a, 8b to the semiconductor element 5, to cause a potential change to occur at the PN junction surfaces of both the source and drain regions. This widens the area of the PN junction surfaces for potential change detection using the LVP technique to increase the accuracy of the inspection of the semiconductor element 5 for the signal change at the input thereof.

The input signal is illustrated above as applied through the CMOS transmission gate 9 to the semiconductor element 5 under test. Instead, the input signal may be applied to the semiconductor element 5 only through the N-channel MOS transistor NT1 or only through the P-channel MOS transistor PT1.

Specifically, the semiconductor device may be configured such that only the N-channel MOS transistor NT1 is provided in the preceding stage of the semiconductor element 5; the input signal to the semiconductor element 5 is applied to the source/drain region 7a; and the source/drain region 7b is connected to the input of the semiconductor element 5. In this case, the power supply potential VCC is applied to the gate electrode 6a, and the ground potential GND is applied to the well 1.

Otherwise, the semiconductor device may be configured such that only the P-channel MOS transistor PT1 is provided in the preceding stage of the semiconductor element 5; the input signal to the semiconductor element 5 is applied to the source/drain region 8a; and the source/drain region 8b is connected to the input of the semiconductor element 5. In this case, the ground potential GND is applied to the gate electrode 6b, and the power supply potential VCC is applied to the well 2.

In this manner, connecting the single MOS transistor, rather than the CMOS transmission gate, to the input of the semiconductor element 5 allows the inspection of the semiconductor element 5 for the signal change at the input thereof. This is because the potential change at the PN junction surface of the source/drain region 7b or 8b connected to the input of the semiconductor element 5 is detectable using the LVP technique.

However, the use of the CMOS transmission gate widens the area of the PN junction surfaces for potential change detection up to the source/drain regions of the two MOS transistors NT1 and PT1 to increase the accuracy of the inspection of the semiconductor element for the signal change at the input thereof.

The two MOS transistors NT1, PT1 may be constructed using redundant transistors formed on the semiconductor substrate 15 but not used as a circuit. When the semiconductor element 5 is a gate array structure or the like, there are always provided gate electrodes and impurity diffused regions which are not in use on the semiconductor substrate. These gate electrodes and impurity diffused regions may be used to constitute the MOS transistors NT1 and PT1.

<Second Preferred Embodiment>

A second preferred embodiment of the present invention shows a modification of the semiconductor device of the first preferred embodiment. According to the second preferred embodiment, a source/drain region serving as the input of the CMOS transmission gate 9 and a source/drain region serving as the output thereof are short-circuited to each other.

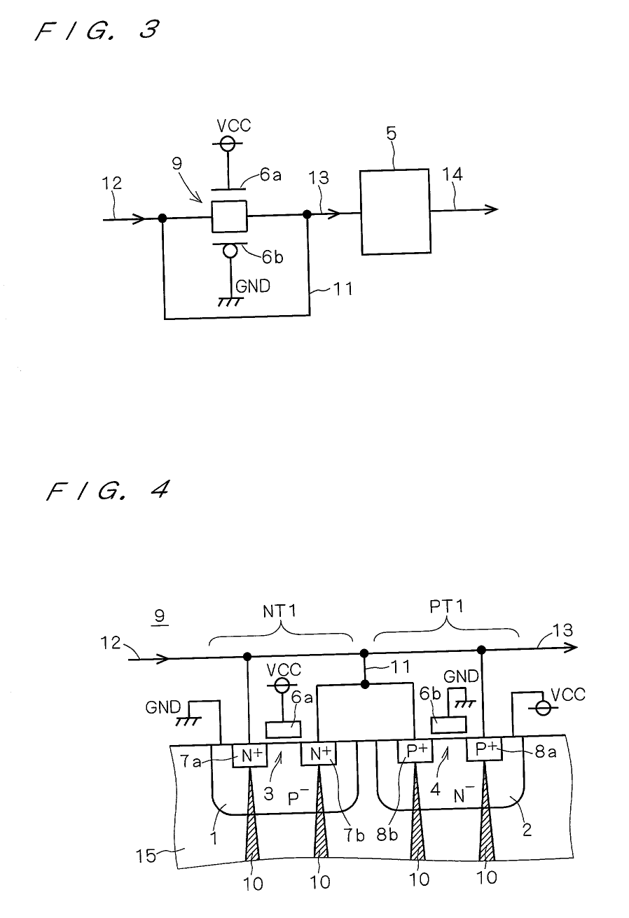

FIGS. 3 and 4 are a circuit diagram and a sectional view, respectively, of the semiconductor device according to the second preferred embodiment. In the semiconductor device, as illustrated in FIG. 3, the input and output of the CMOS transmission gate 9 are short-circuited to each other through an interconnect line 11. Specifically, the source/drain regions 7a and 8a serving as the input are short-circuited to the source/drain regions 7b and 8b serving as the output, respectively, as shown in FIG. 4.

The remaining structure of the semiconductor device of the second preferred embodiment is similar to that of the semiconductor device of the first preferred embodiment, and will not be described herein.

The short-circuiting of the input and output of the CMOS transmission gate 9 causes the input signal to the semiconductor element 5 to bypass a path including the source/drain region 7a, the channel region 3 and the source/drain region 7b of the N-channel MOS transistor NT1 and a path including the source/drain region 8a, the channel region 4 and the source/drain region 8b of the P-channel MOS transistor PT1 and to be transmitted to the input of the semiconductor element 5. This makes signal transmission losses resulting from the parasitic resistance of the paths difficult to produce, to reduce the influence of the provision of the CMOS transmission gate 9 upon the semiconductor element 5.

<Third Preferred Embodiment>

A third preferred embodiment of the present invention shows another modification of the semiconductor device of the first preferred embodiment. According to the third preferred embodiment, the source/drain regions 7a, 8a serving as the input of the CMOS transmission gate 9 and the gate electrodes 6a, 6b are short-circuited.

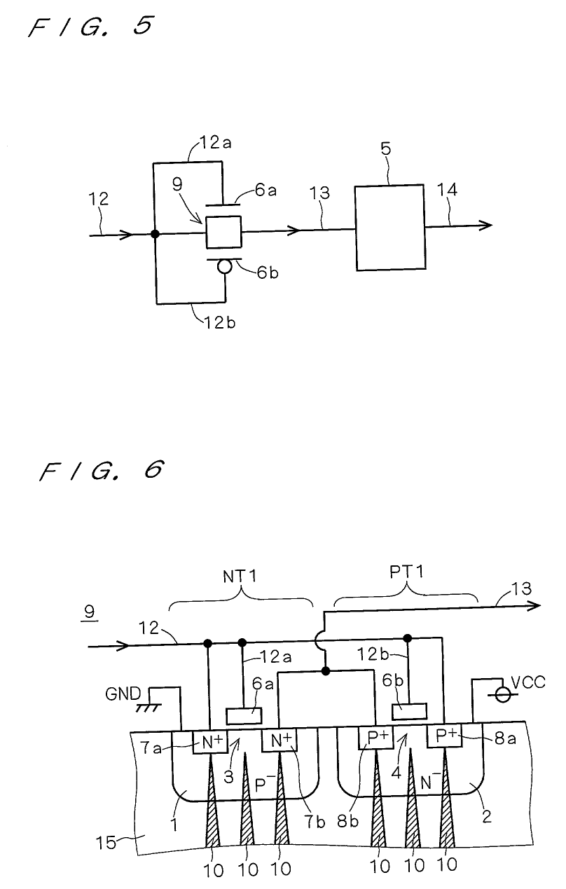

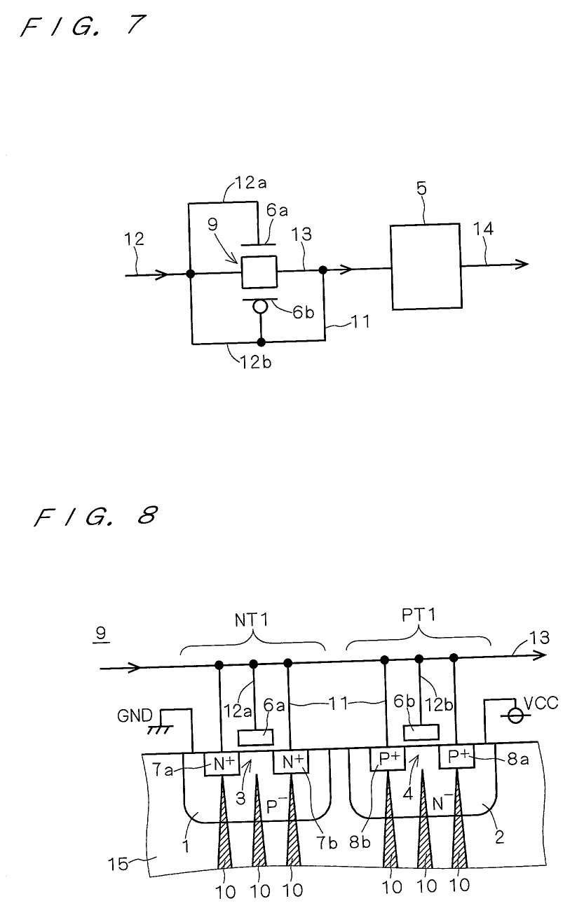

FIGS. 5 and 6 are a circuit diagram and a sectional view, respectively, of the semiconductor device according to the third preferred embodiment. In the semiconductor device, as illustrated in FIGS. 5 and 6, the input of the CMOS transmission gate 9 and the gate electrodes 6a, 6b are short-circuited through interconnect lines 12a, 12b.

The remaining structure of the semiconductor device of the third preferred embodiment is similar to that of the semiconductor device of the first preferred embodiment, and will not be described herein.

The short-circuiting of the source/drain regions 7a, 8a serving as the input of the CMOS transmission gate 9 and the gate electrodes 6a, 6b produces inversion layers in the respective channel regions 3, 4 under the gate electrodes 6a, 6b in response to the potential change of the input signal, to cause the potential change at the PN junction surfaces between the inversion layers and the wells 1, 2. This widens the area of the PN junction surfaces for potential change detection using the LVP technique (i.e., widens the area of detection by directing the near infrared laser beam 10 onto the channel regions 3, 4) to increase the accuracy of the inspection of the semiconductor element for the signal change at the input thereof.

Of course, the detection of the potential change at the PN junction surfaces in the channel regions by the LVP technique using the semiconductor device according to the third preferred embodiment achieves a more accurate testing method capable of detecting the potential change over a wider area extended to the channel regions.

<Fourth Preferred Embodiment>

A fourth preferred embodiment of the present invention is the combination of the second and third preferred embodiments.

FIGS. 7 and 8 are a circuit diagram and a sectional view, respectively, of the semiconductor device according to the fourth preferred embodiment. As illustrated in FIGS. 7 and 8, the input and output of the CMOS transmission gate 9 are short-circuited through the interconnect line 11. Additionally, the input of the CMOS transmission gate 9 and the gate electrodes 6a, 6b are short-circuited through the interconnect lines 12a, 12b.

The remaining structure of the semiconductor device of the fourth preferred embodiment is similar to that of the semiconductor device of the first preferred embodiment, and will not be described herein.

The fourth preferred embodiment provides the semiconductor device which produces both of the effects of the semiconductor device of the second and third preferred embodiments.

<Fifth Preferred Embodiment>

A fifth preferred embodiment of the present invention shows still another modification of the semiconductor device of the first preferred embodiment. The semiconductor device according to the fifth preferred embodiment is configured such that the input signal to the semiconductor element 5 under test is directly applied to the semiconductor element 5 and is applied also to the input of the CMOS transmission gate 9. Also, according to the fifth preferred embodiment, the output of the CMOS transmission gate 9 is short-circuited to the input thereof, and the source/drain regions 7a, 8a serving as the input of the CMOS transmission gate 9 are short-circuited to the gate electrodes 6a, 6b.

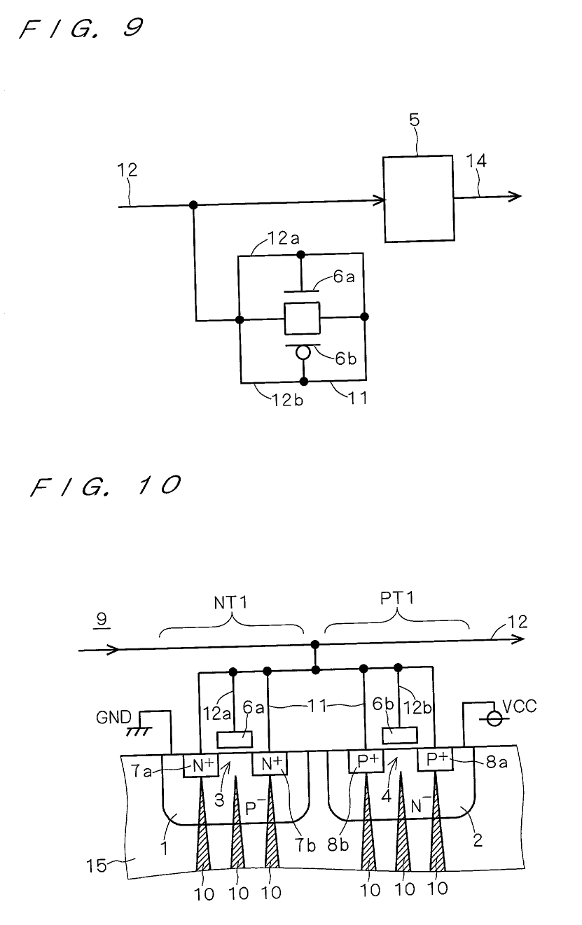

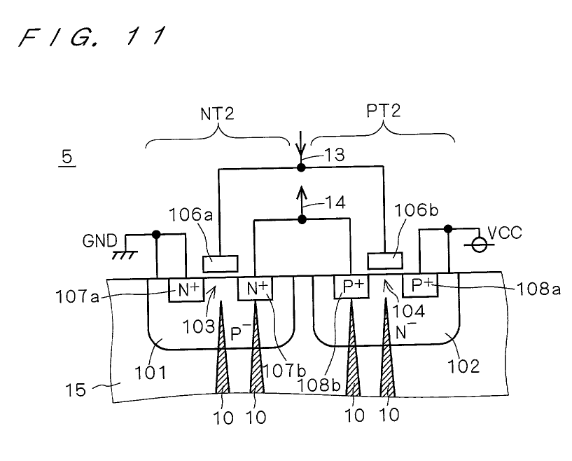

FIGS. 9 and 10 are a circuit diagram and a sectional view, respectively, of the semiconductor device according to the fifth preferred embodiment. In the semiconductor device, as illustrated in FIGS. 9 and 10, the source/drain regions 7a, 8a serving as the input of the CMOS transmission gate 9 are connected to the input of the semiconductor element 5. The input signal to the semiconductor element 5 is applied directly to the semiconductor element 5 through the interconnect line 12 and is applied also to the input of the CMOS transmission gate 9.

In such a configuration that the input signal to the semiconductor element 5 is directly applied to the semiconductor element 5 and is applied also to the input of the CMOS transmission gate 9, the input signal to the semiconductor element 5 is transmitted to the input of the semiconductor element 5 without passing through the paths including the source/drain regions and the channel regions of the CMOS transmission gate 9.

This prevents signal transmission losses resulting from the parasitic resistance of the paths, although the parasitic capacitance of the CMOS transmission gate 9 influences the semiconductor element 5, to reduce the influence of the provision of the CMOS transmission gate 9 upon the semiconductor element 5.

Further, the source/drain regions 7a, 8a serving as the input of the CMOS transmission gate 9 are short-circuited to the source/drain regions 7b, 8b serving as the output thereof according to the fifth preferred embodiment. Moreover, the source/drain regions 7a, 8a are short-circuited to the gate electrodes 6a, 6b through the interconnect lines 12a, 12b.

The remaining structure of the semiconductor device of the fifth preferred embodiment is similar to that of the semiconductor device of the first preferred embodiment, and will not be described herein.

The above-mentioned short-circuiting of the source/drain regions 7a, 7b, 8a, 8b causes a potential change to occur at the PN junction surfaces of both the source and drain regions. This widens the area of the PN junction surfaces for potential change detection using the LVP technique to increase the accuracy of the inspection of the semiconductor element for the signal change at the input thereof.

Further, the above-mentioned short-circuiting of the source/drain regions 7a, 8a serving as the input of the CMOS transmission gate 9 and the gate electrodes 6a, 6b widens the area of the PN junction surfaces for potential change detection using the LVP technique to increase the accuracy of the inspection of the semiconductor element for the signal change at the input thereof, as described with respect to the effect of the semiconductor device of the third preferred embodiment.

In the fifth preferred embodiment, it is not essential to establish the short circuits between the source/drain regions 7a, 8a and the source/drain regions 7b, 8b and between the source/drain regions 7a, 8a and the gate electrodes 6a, 6b. Without these short-circuit configurations, a change in the input signal transmitted through the interconnect line 12 is detectable as a potential change at the PN junction surfaces between the source/drain regions 7a, 8a and the wells 1, 2.

While the invention has been described in detail, the foregoing description is in all aspects illustrative and not restrictive. It is understood that numerous other modifications and variations can be devised without departing from the scope of the invention.

What is claimed is:

1. A semiconductor device having a test element, comprising:
a semiconductor element to be tested, said semiconductor element being formed on a semiconductor substrate and having an input and an output; and
a MIS (metal insulator semiconductor) transistor formed on said semiconductor substrate and serving as said test element, said MIS transistor having a source region defined by a first PN junction surface, a drain region defined by a second PN junction surface, and a gate electrode,
wherein one of said source region and said drain region is connected to said input of said semiconductor element.

2. The semiconductor device according to claim 1, wherein
an input signal to said semiconductor element is applied to the other of said source region and said drain region of said MIS transistor which is not connected to said input of said semiconductor element.

3. The semiconductor device according to claim 2, wherein
said source region and said drain region a re short-circuited to each other.

4. The semiconductor device according to claim 2, wherein
the other of said source region and said drain region to which said input signal is applied is short-circuited to said gate electrode.

5. The semiconductor device according to claim 1, wherein
an input signal to said semiconductor element is applied to said one of said source region and said drain region of said MIS transistor which is connected to said input of said semiconductor element.

6. The semiconductor device according to claim 5, wherein
said source region and said drain region are short-circuited to each other.

7. The semiconductor device according to claim 5, wherein
said one of said source region and said drain region to which said input signal is applied is short-circuited to said gate electrode.

8. The semiconductor device according to claim 1, wherein
said MIS transistor includes at least two MIS transistors, and
said at least two MIS transistors constitute a CMOS transmission gate structure.
